(19) United States
(12) Patent Application Publication
(10) Pub. No.: US 2025/0351526 A1
(43) Pub. Date: Nov. 13, 2025

(54) APPARATUS INCLUDING GATE STRUCTURE ON SEMICONDUCTOR SUBSTRATE

(71) Applicant: Micron Technology, Inc., Boise, ID (US)

(72) Inventors: Yuri Ishizaki, Higashihiroshima (JP); Yoshikazu Moriwaki, Higashihiroshima (JP)

(73) Assignee: Micron Technology, Inc., Boise, ID (US)

(21) Appl. No.: 19/199,670

(22) Filed: May 6, 2025

Related U.S. Application Data
(60) Provisional application No. 63/643,623, filed on May 7, 2024.

(51) Int. Cl. H10D 64/66; H10D 64/68

(52) U.S. Cl. CPC H10D 64/667; H10D 64/675; H10D 64/685

(57) ABSTRACT

Some embodiments of the disclosure provide an apparatus comprising a gate structure on a semiconductor substrate and a liner on a side wall of the gate structure. The side wall of the gate structure include a first spacer and a second spacer on the first spacer. The second spacer has a top portion lower than a top portion of the first spacer. The liner covers at least the second spacer including the top portion thereof.

### CROSS-REFERENCE TO RELATED APPLICATIONS

This application claims the filing benefit of U.S. Provisional Application No. 63/643,623, filed May 7, 2024. This application is incorporated by reference herein in its entirety and for all purposes.

### BACKGROUND

High data reliability, high speed of memory access, low power consumption, and reduced chip size are some features that are demanded from semiconductor memory devices, such as a dynamic random-access memory (DRAM). Transistors, such as field-effect transistors (FETs), included in semiconductor memory devices aim to achieve high performance and low power and at the same time high density and low cost. FETs may be complementary metal-oxide-semiconductors (CMOSs). High Performance CMOSs (HPCs) may rely on a high-k layer to provide high performance with low power and reduced leakage current. However. HPCs may be susceptible to Local Layout Effect (LLE) that may alter characteristics and performance of the transistors. An example effect is variance in threshold voltage Vt of HPC transistors. There is hence a need to reduce or mitigate LLE in semiconductor memory devices that include transistors, such as HPC transistors.

### BRIEF DESCRIPTION OF THE DRAWINGS

FIG. 1 depicts an example configuration of at least part of a semiconductor device in a cross-sectional view according to an embodiment of the disclosure.

FIG. 2 depicts an example configuration of at least part of a semiconductor device in a cross-sectional view according to an embodiment of the disclosure.

### DETAILED DESCRIPTION

Various example embodiments of the disclosure will be described below in detail with reference to the accompanying drawings. The following detailed descriptions refer to the accompanying drawings that show, by way of illustration, specific aspects in which embodiments of the disclosure may be practiced. These embodiments are described in sufficient detail to enable those skilled in the art to practice the disclosure. Other embodiments may be utilized, and structure, logical and electrical changes may be made without departing from the scope of the disclosure. The various embodiments disclosed herein are not necessary mutually exclusive, as some disclosed embodiments can be combined with one or more other disclosed embodiments to form new embodiments.

In the descriptions, common or related elements and elements that are substantially the same are denoted with the same signs, and the descriptions thereof may be reduced or omitted. In the drawings, some of the same signs may be omitted for the same or substantially the same elements for case of illustration. In the drawings, the dimensions and dimensional ratios of each unit do not necessarily match the actual dimensions and dimensional ratios in the embodiments.

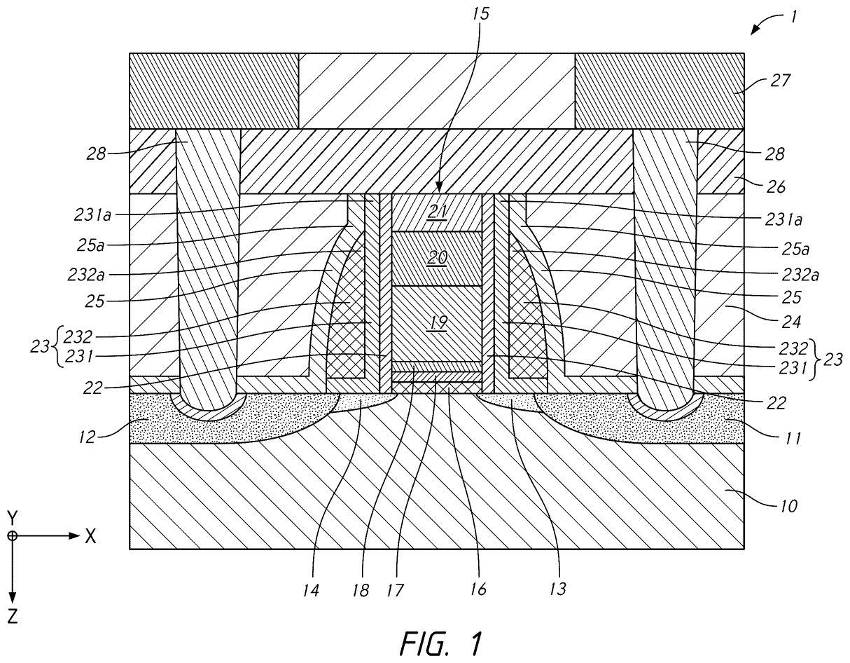

FIG. 1 depicts an example configuration of at least part of a semiconductor device 1 in a cross-sectional view according to an embodiment of the disclosure. The semiconductor device 1 may be one example of an apparatus. The semiconductor device 1 may be a dynamic random-access memory (DRAM). In the example configuration, the semiconductor device 1 includes one or more transistor structures, each including active regions 11 and 12 that are adjacent to lightly-doped regions 13 and 14, respectively, as source/drain regions, formed in a semiconductor substrate 10, and further including a gate structure 15 above a channel region between the active regions 11 and 12. In some instances, the semiconductor device 1 may include a plurality of memory mats arranged in a matrix on the semiconductor substrate 10. Each memory mat may include a plurality of memory cells at intersections of word lines arranged in row and bit lines arranged in column in a memory cell region. The memory mat may include a driver region and a sense amplifier region adjacent to the memory cell region. The driver region may be on sides of the memory cell region in a direction of the word lines (row), and includes, for example, subword drivers, row decoders, and row address latches, each of which uses one or more transistors or transistor structures. The sense amplifier region may be on sides of the memory cell region in a direction of the bit lines (column), and includes, for example, sense amplifiers, column decoders, and column address latches, each of which includes one or more transistors or transistor structures.

The gate structure 15 includes a gate stack with multiple layers stacked on one another on a surface of the semiconductor substrate 10. In the example structure, the gate stack includes a buffer layer 16, a high-k layer 17, a metal gate layer 18, a buffer layer 19, a metal layer 20, and a cap layer 21 stacked on one another in that order on a surface of the semiconductor substrate 10. The buffer layer 16 may be an insulating layer, and may include an insulating material, such as silicon oxide. The high-k layer 17 may include a high-k dielectric material, such as hafnium oxide. The high-k material may have a dielectric constant greater than the insulating material of the buffer layer 16. The metal gate layer 18 may include a metal alloy material, such as titanium nitride. The buffer layer 19 may include a silicon-containing material, such as polycrystalline silicon or polysilicon. The metal layer 20 may include a low resistive metal, such as tungsten. The cap layer 21 may be an insulating layer, and may include an insulating material, such as silicon nitride.

The gate structure 15 further includes a side wall on the gate stack. The side wall includes a double-wall structure which includes a first side wall 22 on a side surface of the gate stack and a second side wall 23 on the first side wall 22. The second side wall 23 includes a first spacer 231 on the first side wall 22 and a second spacer 232 on the first spacer 231. The first side wall 22 may include silicon nitride. The first spacer 231 and the second spacer 232 of the second side wall 23 may include silicon nitride and silicon oxide, respectively.

To provide the gate structure 15 including the side wall on the surface of the substrate 10, first, the multi layers 16-21 are provided on the entire surface of the substrate 10 in that order, and then portions thereof are etched to form the gate stack having a predetermined profile. Subsequently, the first side wall 22 is provided on a side surface of the gate stack by, for example, deposition and etching. Then, the first spacer 231 of the second side wall 23 is deposited and etched on the first side wall 22, and the second spacer 232 is then deposited and etched on the first spacer 231. Conventional deposition and etching techniques may be used as appropriate.

In the example configuration, the gate structure 15 including the side wall is embedded in an interlayer 24 on the surface of the semiconductor substrate 10. The interlayer 24 may be an oxide layer including an oxide material, such as silicon oxide. The side wall of the gate structure 15 is protected by a liner 25 from the material of the interlayer 24, such as the oxide material. The liner 25 may include silicon nitride. In the example configuration, the liner 25 and the second spacer 232 of the second side wall 23 have a specific profile which will be described in detail later.

Besides the gate structure 15, the example configuration includes an insulating layer 26 extending in a horizontal direction (e.g., an X-axis direction in the drawing) above the gate structure 15, a metal layer 27 above the insulating layer 26, and one or more contacts 28 extending from the metal layer 27, penetrating through the insulating layer 26 and the interlayer 24 and reaching at least part of the active regions 11 and 12 of the semiconductor substrate 10 in a vertical direction (e.g., a Z-axis direction in the drawing, perpendicular to the X-axis direction in the X-Y axes plane). The insulating layer 26 may be used as a hard mask to form a bit line. The insulating layer 26 may include an insulating material, such as SiN, SiO, and SiON. In some instances, the insulating material may include a low-k dielectric material, such as SiOC and SiOCN.

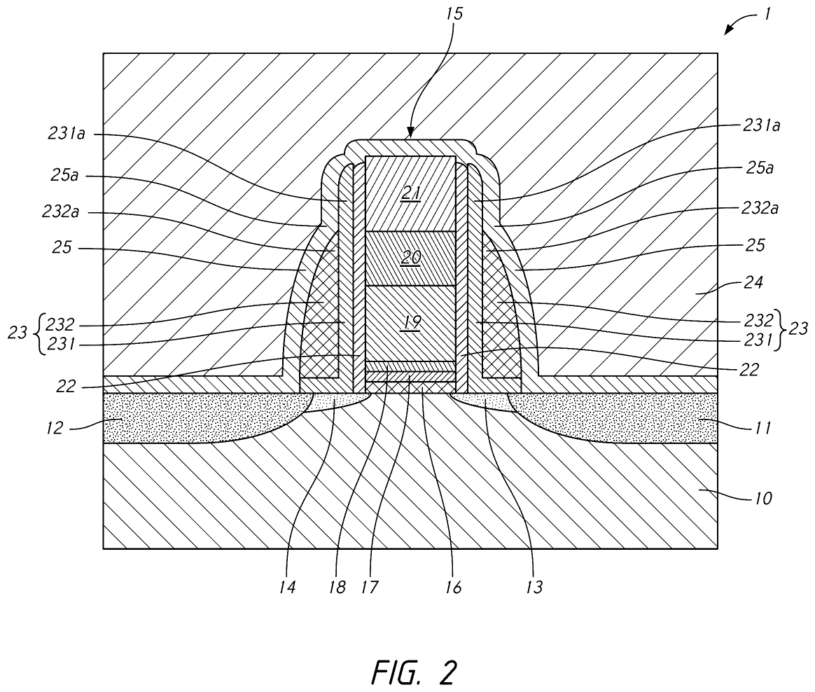

FIG. 2 depicts an example configuration of at least part of the semiconductor device 1 in a cross-sectional view according to an embodiment of the disclosure. The example configuration in FIG. 2 is in a state before the insulating layer 26, the metal layer 27, and the contacts 28 are provided. The second spacer 232 of the second side wall 23 of the gate structure 15 has a top portion 232a lower than a top portion 231a of the first spacer 231 of the second side wall 23, and the liner 25 covers at least the second spacer 232 including the top portion 232a. The liner 25 covers the second spacer 232 such that the second spacer 232 is free from an opening at the top portion 232a thereof. For instance, when a top portion of the gate structure 15 including the gate stack and the side wall as well as the interlayer 24 surrounding the gate structure 15 are removed by, for example, chemical-mechanical polishing (CMP) before providing the insulating layer 26 (FIG. 1), at least the top portion 232a of the second spacer 232 remains covered by the liner 25, and when the insulating layer 26 is formed above the gate structure 15, the liner-covered top portion 232a of the second spacer 232 is not exposed to the insulating layer 26. A top portion 25a of the liner 25 is physically coupled to the insulating layer 26, and the top portion 232a of the second spacer 232 is physically separated from the insulating layer 26. The top portion 231a of the first spacer 231 is physically coupled to the insulating layer 26. In the example structure where the gate structure 15 has the gate stack including the buffer layer 19, the metal layer 20, and the cap layer 21 stacked on one another, the top portion 232a of the second spacer 232 may be formed lower than a top surface of the cap layer 21 and higher than a top surface of the metal layer 20.

To achieve the specific height profile, during the etching of the second spacer 232 of the second side wall 23, a height of the second spacer 232 is adjusted to be a predetermined height lower than a height of the first spacer 231 on the surface of the substrate 10 in the Z-axis direction. Conditions of the etching to achieve the predetermined height may include, for example, a higher selectivity to the material, such as silicon oxide, of the second spacer 232 than the material, such as silicon nitride, of the first spacer 231 so that the second spacer 232 is etched more than the first spacer 231 during the etching of the two spacers when forming the second side wall 23. In one instance, the etching may be dry etching. In one instance, the etching may be anisotropic etching having an etch rate in the vertical or downward direction greater than an etch rate in the horizontal direction. As one non-limiting example, the predetermined height of the second spacer 232 may be lower or shorter than the height of the first spacer 231 for some tens of nanometers.

After the second spacer 232 is formed, the liner 25 is provided to cover the entirety of the gate structure 15 as illustrated in FIG. 2. The liner 25 also covers the surface of the semiconductor substrate 10. The liner 25 may be formed by deposition, such as atomic layer deposition (ALD) and chemical vapor deposition (CVD). Afterward, the interlayer 24 is provided by, for example, spin-on-dielectric (SOD). During SOD, the liner 25 protects the gate structure 15 and the semiconductor substrate 10 from being oxidized by the oxide material of the interlayer 24.

When the top portion of the gate structure 15 is removed and the insulating layer 26 is subsequently formed, since the top portion 232a of the second spacer 232 is positioned sufficiently low, the top portion 232a remains unremoved and covered by the liner 25. Also, since the top portion 232a of the second spacer 232 has a margin from the bottom portion of the insulating layer 26, the top portion 232a does not contact the insulating layer 26 as illustrated in FIG. 1. The top portion 232a of the second spacer 232 does not touch a bottom portion of the insulating layer 26 whereas the top portion 231a of the first spacer 231 and a top portion of the liner 25 contact the insulating layer 26. A top portion of the first side wall 22 also contacts the insulating layer 26.

If the top portion 232a of the second spacer 232 has an opening and contacts the insulating layer 26 without being covered by the liner 25 unlike the example configuration of the present embodiment, a transistor threshold voltage Vt may greatly vary depending on a width dimension (nm) of a gate structure in the X-axis direction due to the exposure of the second spacer 232 to the insulating layer 26. Compared to such a case, in the example configuration, since the top portion 232a of the second spacer 232 is fully covered by the liner 25, leaving no opening that may expose the second spacer 232 to the insulating layer 26 even after the CMP process of the gate structure 15 and the interlayer 24, the gate structure 15 and hence the transistor structure on the semiconductor substrate 10 can stabilize the transistor threshold voltage Vt regardless of the gate width dimension, and hence can effectively reduce or mitigate Local Layout Effect (LLE). Accordingly, transistors, such as High Performance CMOS (HPC) transistors, become less susceptible to LLE.

Although various embodiments of the disclosure have been described in detail, it will be understood by those skilled in the art that embodiments of the disclosure may extend beyond the specifically described embodiments to other alternative embodiments and/or uses and modifications and equivalents thereof. In addition, other modifications which are within the scope of the disclosure will be readily apparent to those of skill in the art based on the described embodiments. It is also contemplated that various combination or sub-combination of the specific features and aspects of the embodiments may be made and still fall within the scope of the disclosure. It should be understood that various features and aspects of the embodiments can be combined with or substituted for one another in order to form varying mode of the embodiments. Thus, it is intended that the scope of the disclosure should not be limited by the particular embodiments described above.

What is claimed is:

1. An apparatus, comprising:
a gate structure on a semiconductor substrate, a side wall of the gate structure including a first spacer and a second spacer on the first spacer, the second spacer having a top portion lower than a top portion of the first spacer, and
a liner on the side wall of the gate structure, the liner configured to cover at least the second spacer including the top portion thereof.

2. The apparatus according to claim 1, wherein the side wall of the gate structure includes a first side wall and a second side wall on the first side wall, and the second side wall includes the first spacer on the first side wall and the second spacer on the first spacer.

3. The apparatus according to claim 2, wherein the gate structure includes a gate stack, and the first side wall is on a side surface of the gate stack.

4. The apparatus according to claim 1, further comprising an insulating layer above the gate structure, wherein a top portion of the liner is physically coupled to the insulating layer and the top portion of the second spacer is physically separated from the insulating layer.

5. The apparatus according to claim 4, wherein the top portion of the first spacer is physically coupled to the insulating layer.

6. The apparatus according to claim 1, further comprising an insulating layer above the gate structure, wherein the top portion of the second spacer covered by the liner does not contact the insulating layer.

7. The apparatus according to claim 1, wherein
the gate structure includes a first layer, a second layer, and a third layer stacked on one another in that order above the semiconductor substrate, and
the top portion of the second spacer is lower than a top surface of the third layer and higher than a top surface of the second layer.

8. The apparatus according to claim 7, wherein the first layer, the second layer, and the third layer includes polysilicon, metal, and an insulating material, respectively.

9. The apparatus according to claim 1, wherein the gate structure is embedded in an interlayer including oxide, and the liner is configured to protect the gate structure from the oxide.

10. The apparatus according to claim 1, wherein the first spacer and the second spacer of the side wall of the gate structure include silicon nitride and silicon oxide, respectively, and the liner includes silicon nitride.

11. An apparatus, comprising:
a gate structure on a semiconductor substrate; and
a liner on a side wall of the gate structure, wherein
the gate structure includes a gate stack and a side wall on the gate stack, the gate stack including a first layer, a second layer, and a third layer stacked on one another in that order above the semiconductor substrate, and the side wall including a first spacer and a second spacer on the first spacer, and
a top portion of the second spacer is lower than a top surface of the third layer and higher than a top surface of the second layer.

12. The apparatus according to claim 11, wherein the top portion of the second spacer is lower than a top portion of the first spacer.

13. The apparatus according to claim 11, wherein the first layer, the second layer, and the third layer of the gate stack includes polysilicon, metal, and an insulating material, respectively.

14. The apparatus according to claim 11, wherein the side wall of the gate structure includes a first side wall on a side surface of the gate stack and a second side wall on the first side wall, and the second side wall includes the first spacer on the first side wall and the second spacer on the first spacer.

15. The apparatus according to claim 11, further comprising an insulating layer above the gate structure, wherein the top portion of the second spacer covered by the liner does not contact the insulating layer.

16. The apparatus according to claim 15, wherein a top portion of the first spacer and a top portion of the liner each contact the insulating layer.

17. The apparatus according to claim 11, wherein the first spacer and the second spacer of the side wall of the gate structure include silicon nitride and silicon oxide, respectively, and the liner includes silicon nitride.

18. An apparatus, comprising:
a gate structure including a gate stack on a semiconductor substrate and a side wall on a side surface of the gate stack, the side wall including a first side wall on the side surface of the gate stack and a second side wall on the first side wall, the second side wall including a first spacer on the first side wall and a second spacer on the first spacer;
a liner configured to cover the side wall of the gate structure; and
an insulating layer above the gate structure, wherein
a top portion of the second spacer is lower than a top portion of the first spacer, and
the top portion of the second spacer is physically separated from the insulating layer.

19. The apparatus according to claim 18, wherein
the gate stack including a first layer, a second layer, and a third layer stacked on one another in that order above the semiconductor substrate, and
the top portion of the second spacer is lower than a top surface of the third layer and higher than a top surface of the second layer.

20. The apparatus according to claim 18, wherein the top portion of the second spacer covered by the liner does not contact the insulating layer, and the top portion of the first spacer and a top portion of the liner each contact the insulating layer.
